(19) United States
(12) Patent Application Publication
(10) Pub. No.: US 2025/0141190 A1
(43) Pub. Date: May 1, 2025

(54) SEMICONDUCTOR LASERS

(71) Applicant: ANHUI GAN SEMICONDUCTOR CO., LTD., Lu'an (CN)

(72) Inventors: Jinjian ZHENG, Lu'an (CN); Shuiqing LI, Lu'an (CN); Jiangyong ZHANG, Lu'an (CN); Wanjun CHEN, Lu'an (CN); Xin CAI, Lu'an (CN)

(73) Assignee: ANHUI GAN SEMICONDUCTOR CO., LTD., Lu'an (CN)

(21) Appl. No.: 18/401,307

(22) Filed: Dec. 29, 2023

Related U.S. Application Data
(63) Continuation of application No. PCT/CN2023/135160, filed on Nov. 29, 2023.

(30) Foreign Application Priority Data
Oct. 25, 2023 (CN) 202311387383.8

(51) Int. Cl. H01S 5/34; H01S 5/22; H01S 5/343

(52) U.S. Cl. CPC H01S 5/3216; H01S 5/02461; H01S 5/305; H01S 5/3406; H01S 5/34333; H01S 5/34346

(57) ABSTRACT

Disclosed is a semiconductor laser, from bottom to top, comprising: a substrate, a lower limiting layer, a lower waveguide layer, an active layer, an upper waveguide layer, and an upper limiting layer. The lower limiting layer is composed of at least one of AllnGaN, AllnN, AlGaN, InN, AlN, InGaN, and GaN. A thickness of the lower limiting layer is denoted as x, and 10 angstroms≤x≤90,000 angstroms. The lower limiting layer includes a first lower limiting layer, a second lower limiting layer, and a third lower limiting layer. The lower limiting layer forms an electron saving structure and a stress regulating structure to regulate a carrier distribution and a stress distribution of the active layer, thereby reducing a threshold current and improving a slope efficiency of the laser.

### CROSS-REFERENCE TO RELATED APPLICATIONS

This application is a Continuation of International Application No. PCT/CN2023/135160, filed on Nov. 29, 2023, which claims priority of the Chinese Patent Application No. 202311387383.8, filed on Oct. 25, 2023, the entire content of which are hereby incorporated by reference.

### TECHNICAL FIELD

The present disclosure relates to the technical field of semiconductor optoelectronic devices, and in particular to a semiconductor laser.

### BACKGROUND

Lasers are widely used in the fields of laser displays, laser TVs, laser projectors, communications, medical, weapons, guidance, atomic clocks, ranging, spectral analysis, cutting, undersea communications, precision welding, quantum sensors, high-density optical storage, etc. There are many types of lasers categorized in various ways, mainly including solid, gas, liquid, semiconductor and dye lasers. Compared with other types of lasers, all-solid-state semiconductor lasers have the advantages of good monochromaticity, good directionality, small size, high brightness, high efficiency, light weight, good stability, long service life, simple and compact structure, and miniaturization.

Lasers and nitride semiconductor light-emitting diodes are quite different. The differences may include: 1) laser is generated by carriers undergoing excited radiation, which is low in spectral half-height width and high in brightness, and the output power of a single laser may be in a W level, while the nitride semiconductor light-emitting diode is generated by spontaneous radiation, and the output power of a single light-emitting diode may be in a mW level; 2) a use current density of the lasers may be up to KA/cm², 2 orders of magnitude higher than that of the nitride light-emitting diode, thereby causing stronger electron leakage, more serious Auger recombination, stronger polarization effect, and more serious electron-hole mismatch, resulting in more serious Droop effect; 3) the nitride semiconductor light-emitting diode has spontaneous transition radiation from high-energy-level incoherent light to low-energy-level incoherent light without external action, while the laser is implemented by excited transition radiation, the induced photon energy is equal to a difference between the energy levels of the electron transition, resulting in identical coherent light of photons and induced photons; 4) the principle is different: the light-emitting diode is that under the action of an external voltage, electron holes jump to an active layer or a p-n junction to produce radiative recombination light, while the lasers need to meet the condition of excitation of an inversion distribution in an active zone carrier before being excited. The excited radiation light oscillates back and forth in a resonant cavity to realize light amplification by propagating in a gain medium, so that a threshold condition is met, the gain is greater than the loss, and laser light is ultimately output. The nitride semiconductor lasers have the following problems: the lasers use a large current, resulting in a large current density and high heat generation. In addition, the lasers have poor heat dissipation and poor temperature characteristics, exacerbating the thermal mismatch between the semiconductor epitaxial layers, resulting in a rise in the threshold current, a decrease in the output optical power and slope efficiency, etc. Non-radiative recombination loss may occur in the active region of the laser chip and free carriers may absorb a large amount of heat. Meanwhile, the epitaxial and chip material has resistance, which may produce Joule heat loss and carrier absorption loss in the current injection. In addition, the chip material has low thermal conductivity and poor heat dissipation performance, resulting in a rise in the temperature of the active layer, and problems of excitation wavelength redshift, a decrease in quantum efficiency, a decrease in power, an increase in the threshold current, a decrease in the service life, the reliability deterioration, etc.

The internal optical absorption loss of the laser may include impurity absorption loss, carrier absorption loss, scattering loss of a waveguide structure sidewall, quantum well absorption loss, etc. The optical waveguide impurity absorption loss is high, and the inherent carbon impurities in p-type semiconductors may compensate for the acceptor, destruct p-type, etc., The dissociation rate of p-type doping is low (less than 10%), and a large number of un-ionized Mg acceptor impurities (more than 90%) may produce self-compensation effect and cause a rise in the internal optical loss, resulting in a decrease in the laser slope efficiency and an increase in the threshold current. In addition, the refractive index dispersion of the laser, the concentration of high-concentration carriers fluctuates to affect the refractive index of the active layer, and the limiting factor decreases with the increase in wavelength, resulting in a decrease in the modal gain of the laser.

The fewer the laser modes, the better for excited radiation, the better for increasing the degeneracy of photons, and the better for making the excited radiation exceed the spontaneous radiation. The laser modes can be reduced by using a Fabry-Perot optical resonant cavity. A standing wave along an axial direction of the cavity is referred to as a longitudinal mode. A transverse mode of a light field is formed when the light field is transversely distributed in a cavity direction. Light is reflected back and forth between two mirrors, and when an isophase plane of light waves is equal to a radius of curvature of the mirrors, the formed transverse mode of the light field is transversely invariant. The pattern of the laser light waves may be divided into the transverse mode and the longitudinal mode. A light intensity distribution of the transverse mode within a cross section perpendicular to an optical axis may be determined by a waveguide structure of the semiconductor laser. If the transverse mode is complex and unstable, output light may be poorly coherent. The longitudinal mode has a standing wave distribution in a propagation direction of the resonant cavity, and a lot of longitudinal modes may be excited simultaneously or have intermodal variations, so that a high temporal coherence may not be obtained, and a far-field image is poor in far-field pattern (FFP) quality.

Therefore, it is desirable to provide a semiconductor laser capable of ensuring the coherence of the transverse modes and reducing a count of the longitudinal modes and the intermodal variations, thereby enhancing the temporal coherence of the longitudinal modes and the FFP quality of the far-field image.

### SUMMARY

In order to remedy the insufficiencies of the prior art, the present disclosure provides a semiconductor laser.

The presents disclosure solves the technical problems using the following technical solutions.

One or more embodiments of the present disclosure provides a semiconductor laser. The semiconductor laser may comprise, from bottom to top, a substrate, a lower limiting layer, a lower waveguide layer, an active layer, an upper waveguide layer, and an upper limiting layer. The lower limiting layer may be composed of at least one of AllnGaN, AllnN, AlGaN, InN, AlN, InGaN, and GaN. A thickness of the lower limiting layer may be denoted as x, and 10 angstroms≤x≤90,000 angstroms. The lower limiting layer may include a first lower limiting layer, a second lower limiting layer, and a third lower limiting layer.

In some embodiments, thermal conductivities of the first lower limiting layer, the second lower limiting layer, the third lower limiting layer may be denoted as a, b, and c, respectively, and 2.5 (10⁻⁶/K)≤b≤a≤c≤5.5 (10⁻⁶/K). Electron effective masses of the first lower limiting layer, the second lower limiting layer, the third lower limiting layer may be denoted as d, e, and f, respectively, and 200 me≤e≤f≤d≤400 me. Phillips ionizations of the first lower limiting layer, the second lower limiting layer, the third lower limiting layer may be denoted as g, h, and I, respectively, and 3≤i≤g≤h≤4.

In some embodiments, a ratio of a content of an element In to a content of an element Mg of the second lower limiting layer and a ratio of a content of an element Si to the content of the element Mg of the second lower limiting layer may have an inverted “U”-shaped distribution. A ratio of a content of an element Al to the content of the element Mg of the second lower limiting layer may have a “U”-shaped distribution.

In some embodiments, a thermal conductivity distribution and an electron effective mass distribution of the second lower limiting layer may have an “U”-shaped distribution. A Phillips ionization distribution and an electron affinity energy distribution of the second lower limiting layer may have an inverted “U”-shaped distribution.

In some embodiments, the thermal conductivity distribution of the second lower limiting layer may correspond to a curvilinear distribution of a first function, the first function being denoted as y=ix²+jx+k (i>0). The electron effective mass distribution of the second lower limiting layer may correspond to a curvilinear distribution of a second function, the second function being denoted as y=mx²+nx+0 (m>0). The Phillips ionization distribution of the second lower limiting layer may correspond to a curvilinear distribution of a third function, the third function being denoted as y=px²+qx+r (p<0). The electron affinity energy distribution of the second lower limiting layer may correspond to a curvilinear distribution of a fourth function, the fourth function being denoted as y=sx²+tx+u (s<0), wherein s<p<0<i≤m, and j, k, n, o, q, r, t, and u may be any preset values.

In some embodiments, the active layer may be a periodic structure composed of well layers and barrier layers. The periodic structure may include 1-3 sets of well layers and barrier layers. Each of the well layers and each of the barrier layers may be composed of at least one of GaN, InGaN, InN, AllnN, AlGaN, AllnGaN, AlN, GaAs, GaP, InP, AlGaAs, AllnGaAs, AlGalnP, InGaAs, InGaAsN, AllnAs, AllnP, AlGaP, InGaP, GaSb, InSb, InAs, InAsSb, AlGaSb, AISb, InGaSb, AlGaAsSb, InGaAsSb, SiC, Ga₂O₃, BN, and diamond. A thickness of each of the well layers may be within a range of 10 angstroms to 120 angstroms. A thickness of each of the barrier layers may be within a range of 10 angstroms to 200 angstroms. A refractive index coefficient of each of the well layers may be greater than or equal to a refractive index coefficient of each of the barrier layers. A dielectric constant of each of the well layers may be greater than or equal to a dielectric constant of each of the barrier layers. A piezoelectric polarization coefficient of each of the well layers may be greater than or equal to a piezoelectric polarization coefficient of each of the barrier layers.

In some embodiments, the active layer may include a first active layer and a second active layer. The refractive index coefficients of the well layers and the barrier layers of the first active layer may be denoted as A and B, respectively, and the refractive index coefficients of the well layers and the barrier layers of the second active layer may be denoted as C and D, respectively, and 2.0≤B≤D≤A≤C≤3.0. The dielectric constants of the well layers and the barrier layers of the first active layer may be denoted as E and F, respectively, and the dielectric constants of the well layers and the barrier layers of the second active layer may be denoted as G and H, respectively, and 8≤G≤ESH≤F≤12. The piezoelectric polarization coefficients of the well layers and the barrier layers of the first active layer may be denoted as I and J, respectively, and the piezoelectric polarization coefficients of the well layers and the barrier layers of the second active layer may be denoted as K and L, respectively, and 0.7≤J≤L≤I≤K≤1.0.

In some embodiments, the refractive index coefficient, the dielectric constant, and the piezoelectric polarization coefficient of the first active layer may have a W-shaped distribution. The refractive index coefficient, the dielectric constant, and the piezoelectric polarization coefficient of the second active layer may have an M-shaped distribution.

In some embodiments, the upper waveguide layer may be an upper waveguide layer for suppressing optical absorption loss. The upper waveguide layer may be composed of at least one of GaN, InGaN, InN, AllnN, AllnGaN, AlN, GaAs, GaP, InP, AlGaAs, AllnGaAs, AlGalnP, InGaAs, AllnAs, AllnP, AIGaP, InGaP, GaSb, InSb, InAs, AlGaSb, AISb, InGaSb, AlGaAsSb, InGaAsSb, SiC, Ga₂O₃, BN, and diamond. A thickness of the upper waveguide layer may be within a range of 200 angstroms to 8000 angstroms. A conduction band effective density distribution, an electron affinity energy distribution, and a breakdown field strength distribution of the upper waveguide layer may present an arc-shaped distribution. The conduction band effective density distribution may correspond to a curvilinear distribution of a fifth function, the fifth function being denoted as y=logᵥ×(0<v<1). The electron affinity distribution may correspond to a curvilinear distribution of a sixth function, the sixth function being denoted as y=log_{w}×(w>1). The breakdown field strength distribution may correspond to a curvilinear distribution of a seventh function, the seventh function being denoted as y=log_{z}×(z>1), wherein 0<v<1<w<z<500.

In some embodiments, the lower waveguide layer and the upper limiting layer may be respectively composed of at least one of GaN, InGaN, InN, AllnN, AllnGaN, AlN, GaAs, GaP, InP, AlGaAs, AllnGaAs, AlGalnP, InGaAs, respectively, AllnAs, AllnP, AlGaP, InGaP, GaSb, InSb, InAs, AlGaSb, AISb, InGaSb, AlGaAsSb, InGaAsSb, SiC, Ga₂O₃, BN, and diamond. A thickness of the lower waveguide layer may be within a range of 10 angstroms to 50,000 angstroms. A thickness of the upper limiting layer may be within a range of 10 angstroms to 80,000 angstroms. The substrate may include any one of sapphire, Si, Ge, SiC, AlN, GaN, GaAs, Cu, W, Mo, TiW, GaSb, InSb, InP, a sapphire/SiO₂ composite substrate, a sapphire/AlN composite substrate, sapphire/SiNₓ, magnesium aluminum spinel MgAl₂O₄, MgO, ZnO, MgO, spinel, ZrB₂, diamond, LiAlO₂, and a LiGaO₂ composite substrate.

### BRIEF DESCRIPTION OF THE DRAWINGS

The present disclosure will be further illustrated by way of exemplary embodiments, which will be described in detail with reference to the accompanying drawings. These embodiments are not limiting. In these embodiments, the same numbering indicates the same structure, wherein:

FIG. 1 is a schematic structural diagram illustrating a semiconductor laser according to some embodiments of the present disclosure;

FIG. 2 is a secondary ion mass spectroscopy (SIMS) of a semiconductor laser according to some embodiments of the present disclosure;

FIG. 3 is a secondary ion mass spectroscopy (SIMS) of a semiconductor laser according to some embodiments of the present disclosure;

FIG. 4 is a transmission electron microscope (TEM) image of a lower limiting layer of a semiconductor laser obtained by a TEM with a size of 200 nm according to some embodiments of the present disclosure;

FIG. 5 is a transmission electron microscope (TEM) image of a lower limiting layer and a lower waveguide layer of a semiconductor laser obtained by a TEM with a size of 500 nm according to some embodiments of the present disclosure;

FIG. 6 is a transmission electron microscope (TEM) image of an active layer of a semiconductor laser obtained by a TEM with a size of 20 nm according to some embodiments of the present disclosure;

FIG. 7 is a transmission electron microscope (TEM) image of an upper waveguide layer and a lower waveguide layer of a semiconductor laser obtained by a TEM with a size of 200 nm according to some embodiments of the present disclosure; and

FIG. 8 is a transmission electron microscope (TEM) image of an upper limiting layer of a semiconductor laser obtained by a TEM with a size of 100 nm according to some embodiments of the present disclosure.

Reference signs: 100: Substrate; 101: Lower limiting layer; 101a: First lower limiting layer; 101b: Second lower limiting layer; 101c: Third lower limiting layer; 102: Lower waveguide layer; 103: Active layer; 104: Upper waveguide layer; 105: Upper limiting layer.

### DETAILED DESCRIPTION

In order to more clearly illustrate the technical solutions of the embodiments of the present disclosure, the following briefly introduces the drawings that need to be used in the description of the embodiments. Apparently, the accompanying drawings in the following description are only some examples or embodiments of the present disclosure, and those skilled in the art can also apply the present disclosure to other similar scenarios according to the drawings without creative efforts. Unless obviously obtained from the context or the context illustrates otherwise, the same numeral in the drawings refers to the same structure or operation.

As indicated in the disclosure and claims, the terms “a”, “an” and/or “the” are not specific to the singular form and may include the plural form unless the context clearly indicates an exception. Generally speaking, the terms “comprising” and “including” only suggest the inclusion of clearly identified steps and elements, and these steps and elements do not constitute an exclusive list, and the method or device may also contain other steps or elements.

In order to make the technical means, creative features, purposes and effects realized in the present disclosure easy to understand, the present disclosure will be further illustrated by way of exemplary embodiments.

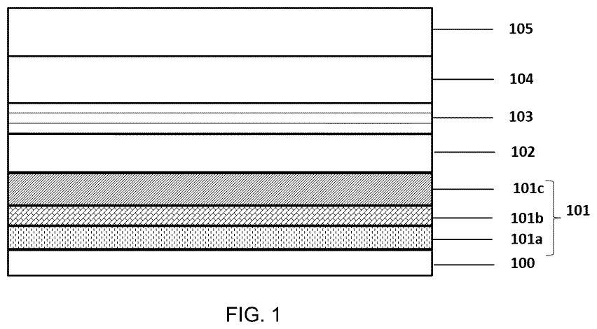

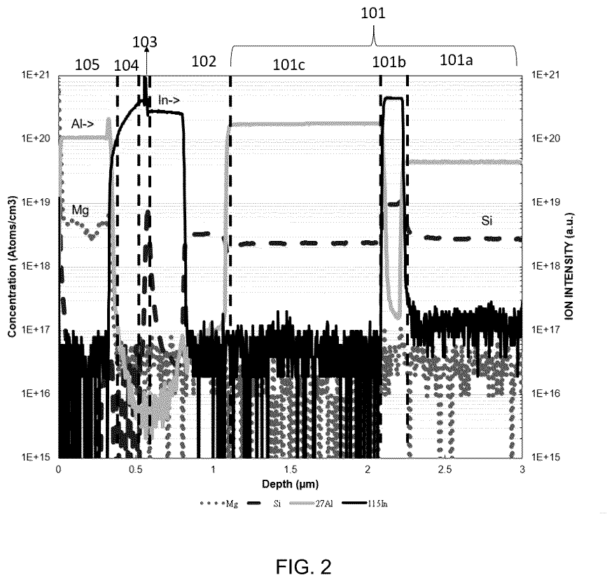

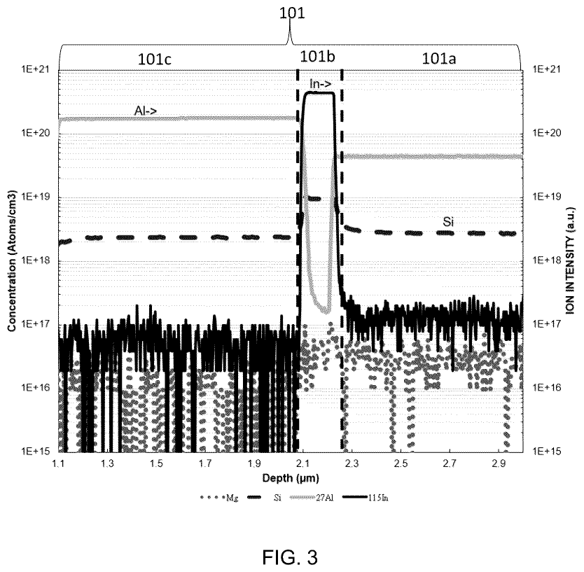

FIG. 1 is a schematic structural diagram illustrating a semiconductor laser according to some embodiments of the present disclosure. FIG. 2 is a secondary ion mass spectroscopy (SIMS) of a semiconductor laser according to some embodiments of the present disclosure. FIG. 3 is a secondary ion mass spectroscopy (SIMS) of a semiconductor laser according to some embodiments of the present disclosure.

A horizontal axis in FIG. 2 and FIG. 3 represents a depth of each element in the semiconductor laser, respectively, measured in μm. A left vertical axis in FIG. 2 and FIG. 3 represents a concentration of each element in each layer of the semiconductor laser, respectively, measured in atoms/cm³. A right vertical axis in FIG. 2 and FIG. 3 represents an ionic strength of each element in each layer of the semiconductor laser, respectively, measured in a.u. (atomic units).

As illustrated in FIGS. 1-3, the embodiment of the present disclosure provides a semiconductor laser, comprising, from bottom to top, a substrate 100, a lower limiting layer 101, a lower waveguide layer 102, an active layer 103, an upper waveguide layer 104, and an upper limiting layer 105.

The lower limiting layer 101 may be configured to regulate a carrier distribution and a stress distribution of the active layer 103, as well as to reduce heat buildup in the active layer 103.

In some embodiments, the lower limiting layer 101 may be composed of at least one of AllnGaN, AllnN, AlGaN, InN, AlN, InGaN, and GaN. For example, the lower limiting layer 101 may be composed of AllnGaN and AllnN.

In some embodiments, a thickness of the lower limiting layer 101 may be denoted as x, and 10 angstroms≤x≤90,000 angstroms. For example, the thickness x of the lower limiting layer may be 10 angstroms. As another example, the thickness x of the lower limiting layer may be 44,995 angstroms. As another example, the thickness x of the lower limiting layer may be 90,000 angstroms.

In some embodiments of the present disclosure, coherence of transverse modes is ensured and a count of longitudinal modes and intermodal variations are reduced by setting the lower limiting layer as a three-layer structure, setting the thickness of the lower limiting layer to be within the range of 10 angstroms<x≤90,000 angstroms, and setting the lower limiting layer to be composed of at least one of AllnGaN, AllnN, AlGaN, InN, AlN, InGaN, and GaN, thereby improving the temporal coherence of the longitudinal modes and the FFP quality of a far-field image.

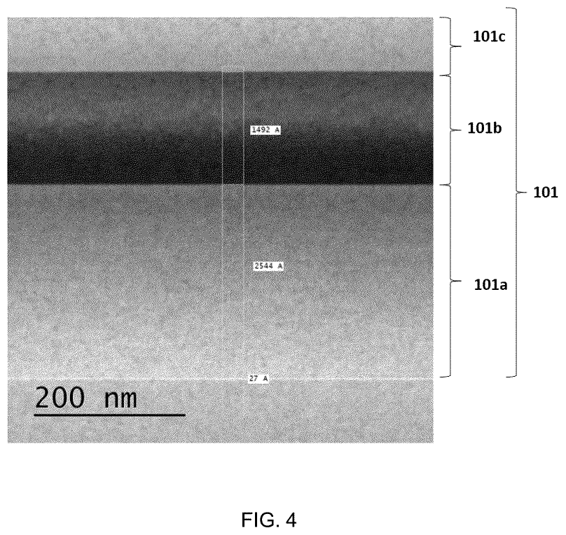

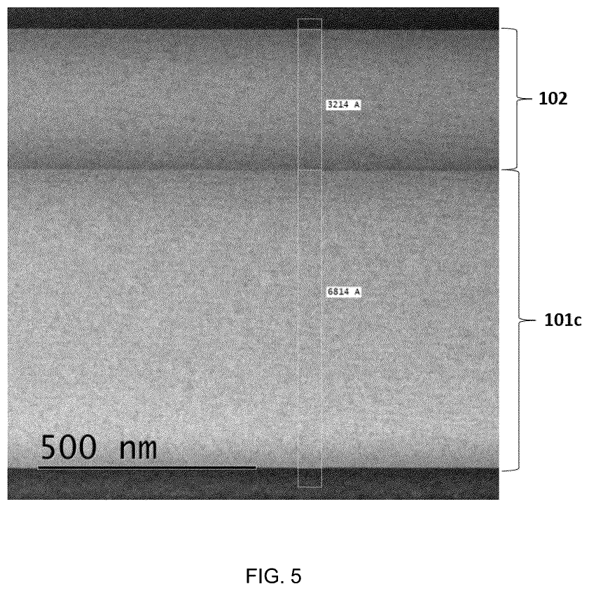

FIG. 4 is a transmission electron microscope (TEM) image of a lower limiting layer of a semiconductor laser obtained by a TEM with a size of 200 nm according to some embodiments of the present disclosure. FIG. 5 is a transmission electron microscope (TEM) image of a lower limiting layer and a lower waveguide layer of a semiconductor laser obtained by a TEM with a size of 500 nm according to some embodiments of the present disclosure.

In some embodiments, as illustrated in FIG. 4, the lower limiting layer 101 may include a first lower limiting layer 101a, a second lower limiting layer 101b, and a third lower limiting layer 101c.

The first lower limiting layer 101a refers to a lower limiting layer adjacent to the substrate 100.

The second lower limiting layer 101b refers to a lower limiting layer located between the first lower limiting layer 101a and the third lower limiting layer 101c.

As illustrated in FIG. 5, the third lower limiting layer 101c refers to a lower limiting layer adjacent to the lower waveguide layer 102.

In some embodiments, thermal conductivities of the first lower limiting layer 101a, the second lower limiting layer 101b, and the third lower limiting layer 101c may be denoted as a, b, and c, respectively, and 2.5 (10⁻⁶/K)≤b≤a≤c≤5.5 (10⁻⁶/K). For example, the thermal conductivities of the first lower limiting layer 101a, the second lower limiting layer 101b, and the third lower limiting layer 101c may be denoted as a=3.5 (10⁻⁶/K), b=2.5 (10⁻⁶/K), and c=5.5 (10⁻⁶/K), respectively.

The thermal conductivity may be used to characterize a degree of thermal conductivity of the lower limiting layer (e.g., the first lower limiting layer 101a, the second lower limiting layer 101b, and the third lower limiting layer 101c).

In some embodiments, electron effective masses of the first lower limiting layer 101a, the second lower limiting layer 101b, and the third lower limiting layer 101c may be denoted as d, e, and f, respectively, and 200 me≤e≤f≤d≤400 me. For example, the electron effective masses of the first lower limiting layer 101a, the second lower limiting layer 101b, and the third lower limiting layer 101c may be denoted as d=400 me, e=200 me, and f=300 me, respectively.

The electron effective mass may be used to characterize a magnitude of a force of a potential field within the lower limiting layer (e.g., the first lower limiting layer 101a, the lower second limiting layer 101b, and the third lower limiting layer 101c).

In some embodiments, Phillips ionizations of the first lower limiting layer 101a, the second lower limiting layer 101b, and the third lower limiting layer 101c may be denoted as g, h, and i, respectively, and 3≤i≤g≤h≤4. For example, the Phillips ionizations of the first lower limiting layer 101a, the second lower limiting layer 101b, and the third lower limiting layer 101c may be denoted as g=3.5, h=4, and i=3, respectively.

The Phillips ionization may be used to characterize a ratio of ionizable particles to total particles in the lower limiting layer (e.g., the first lower limiting layer 101a, the second limiting layer 101b, and the third limiting layer 101c).

In some embodiments of the present disclosure, the heat buildup in the active layer can be effectively reduced by setting the thermal conductivities of the first lower limiting layer 101a, the second lower limiting layer 101b, and the third lower limiting layer 101c as a, b, and c, respectively, wherein 2.5 (10⁻⁶/K)≤b≤a≤c≤5.5 (10⁻⁶/K); the stress distribution of the active layer can be in an optimal status by setting the electron effective masses of the first lower limiting layer 101a, the second lower limiting layer 101b, and the third lower limiting layer 101c as d, e, and f, respectively, wherein 200 m≤e≤f≤d≤400 me; and the carrier distribution of the active layer can be in an optimal status by setting the Phillips ionizations of the first lower limiting layer 101a, the second lower limiting layer 101b, and the third lower limiting layer 101c as g, h, and i, respectively, wherein 3≤i≤g≤h≤4, thereby further ensuring the coherence of the transverse modes, reducing the count of the longitudinal modes and the intermodal variations, and improving the temporal coherence of the longitudinal modes and the FFP quality of the far-field image.

In some embodiments, a ratio of a content of an element In to a content of an element Mg of the second lower limiting layer and a ratio of a content of an element Si to the content of the element Mg of the second lower limiting layer may have an inverted “U”-shaped distribution. A ratio of a content of an element Al to the content of the element Mg of the second lower limiting layer may have a “U”-shaped distribution.

The ratio of the content of the element In to the content of the element Mg refers to a ratio of a mass of the element In to a mass of the element Mg in each of a plurality of regions defined in the second lower limiting layer. The second lower limiting layer may be divided into the plurality of regions in various ways. For example, the second lower limiting layer may be equally divided into n regions, wherein n>2 and n may be a positive integer.

The ratio of the content of the element Si to the content of the element Mg refers to a ratio of a mass of the element Si to the mass of element Mg in each of the plurality of regions defined in the second lower limiting layer.

The ratio of the content of the element In to the content of the element Mg having the inverted “U”-shaped distribution refers to that a distribution of a ratio of the content of the element In to the content of the element Mg in each of the plurality of regions defined in the second lower limiting layer has an inverted “U”-shaped distribution.

The ratio of the content of the element Si to the content of the element Mg having the inverted “U”-shaped distribution, and the ratio of the content of the element Al to the content of the element Mg having the “U”-shaped distribution may have similar meanings as the ratio of the content of the element In to the content of the element Mg having the inverted “U”-shaped distribution, which may be found in the above descriptions.

In some embodiments of the present disclosure, by setting the ratio of the content of the element In to the content of the element Mg of the second lower limiting layer and the ratio of the content of the element Si to the content of the element Mg of the second lower limiting layer as the inverted “U”-shaped distribution, and the ratio of the content of the element Al to the content of the element Mg of the second lower limiting layer as the “U”-shaped distribution, a thermal expansion coefficient of the second lower limiting layer may have an inverted “U”-shaped distribution, an elasticity coefficient of the second lower limiting layer may have a “U”-shaped distribution, and a lattice constant of the second lower limiting layer may have a forward “n”-shaped distribution, so that an electron saving structure and a stress regulating structure may be formed to regulate the carrier distribution and the stress distribution of the active layer, thereby reducing the threshold current and improving the slope efficiency of the laser. Meanwhile, the Auger non-radiative recombination efficiency may be suppressed, heat generated by the non-radiative recombination loss and the free carrier absorption loss may be reduced, and heat buildup in the active layer may be reduced, thereby improving the thermal conductivity and heat dissipation, and improving 1000 H aging optical degradation of the laser from 22% to be within 4% and improving focusing spot resolution of the laser from over 200 nm to be less than 40 nm.

In some embodiments, a thermal conductivity distribution and an electron effective mass distribution of the second lower limiting layer may have an “U”-shaped distribution. A Phillips ionization distribution and an electron affinity energy distribution of the second lower limiting layer may have an inverted “U”-shaped distribution.

The thermal conductivity distribution refers to a distribution of thermal conductivities in each of the plurality of regions defined in the second lower limiting layer.

The electron effective mass distribution refers to a distribution of a magnitude of a potential field force within each of the plurality of regions defined in the second lower limiting layer.

The Phillips ionization distribution refers to a distribution of Phillips ionizations within each of the plurality of regions defined in the second lower limiting layer.

The electron affinity energy distribution refers to a distribution of an ability of each atomic center to gain electrons within the second lower limiting layer.

In some embodiments of the present disclosure, by setting the thermal conductivity distribution and the electron effective mass distribution of the second lower limiting layer as the “U”-shaped distribution, and the Phillips ionization distribution and the electron affinity energy distribution of the second lower limiting layer as the inverted “U”-shaped distribution, the thermal expansion coefficient of the second lower limiting layer may have the inverted “U”-shaped distribution, the elasticity coefficient of the second lower limiting layer may have the “U”-shaped distribution, and the lattice constant of the second lower limiting layer may have the forward “n”-shaped distribution, so that the electron saving structure and the stress regulating structure may be formed to regulate the carrier distribution and the stress distribution of the active layer, thereby reducing the threshold current and improving the slope efficiency of the laser.

In some embodiments, the thermal conductivity distribution of the second lower limiting layer 101b may correspond to a curvilinear distribution of a first function, the first function being denoted as y=ix²+jx+k (i>0).

In some embodiments, the electron effective mass distribution of the second lower limiting layer 101b may correspond to a curvilinear distribution of a second function, the second function being denoted as y=mx²+nx+0 (m>0).

In some embodiments, the Phillips ionization distribution of the second lower limiting layer 101b may correspond to a curvilinear distribution of a third function, the third function being denoted as y=px²+qx+r (p<0).

In some embodiments, the electron affinity energy distribution of the second lower limiting layer 101b may correspond to a curvilinear distribution of a fourth function, the fourth function being denoted as y=sx²+tx+u (s<0), wherein s<p<0<ism, and j, k, n, o, q, r, t, and u may be any preset values and may be predetermined by those skilled in the art based on experience.

In some embodiments of the present disclosure, the thermal conductivity distribution, the electron effective mass distribution, the Phillips ionization distribution, and the electron affinity energy distribution of the second lower limiting layer may be set to correspond to the specific function curves, so that the thermal conductivity distribution and the electron effective mass distribution of the second lower limiting layer may be closer to the “U”-shaped distribution, the Phillips ionization distribution and the electron affinity energy distribution of the second lower limiting layer may be closer to the inverted “U”-shaped distribution, the thermal expansion coefficient of the second lower limiting layer may have the inverted “U”-shaped distribution, the elasticity coefficient of the second lower limiting layer may have the “U”-shaped distribution, and the lattice constant of the second lower limiting layer may have the forward “n”-shaped distribution, and thus the electron saving structure and the stress regulating structure may be formed to regulate the carrier distribution and the stress distribution of the active layer, thereby reducing the threshold current and improving the slope efficiency of the laser.

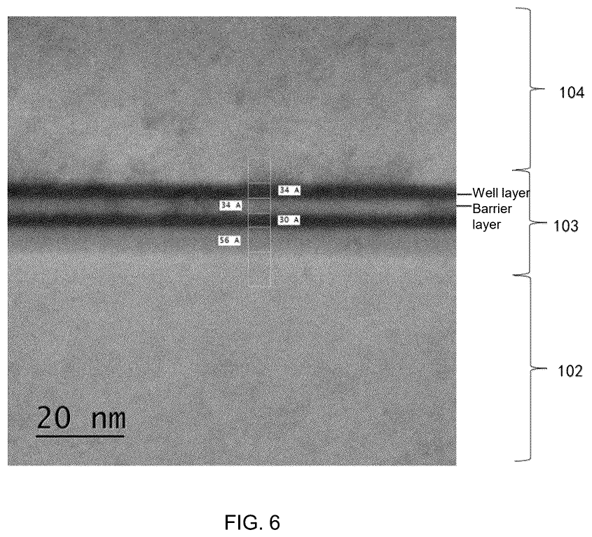

FIG. 6 is a transmission electron microscope (TEM) image of an active layer of a semiconductor laser obtained by a TEM with a size of 20 nm according to some embodiments of the present disclosure

The active layer refers to a thin layer used to generate photons and amplify light.

In some embodiments, as illustrated in FIG. 6, the active layer 103 may be a periodic structure composed of well layers and barrier layers. In some embodiments, the periodic structure may include 1-3 sets of well layers and barrier layers.

The well layer refers to a region of the semiconductor laser where an electron energy is higher than a valence band but lower than a conduction band.

The barrier layer refers to a blocking layer formed in a PN junction of the semiconductor laser due to diffusion of electrons and holes.

In some embodiments, each of the well layers and each of the barrier layers may be composed of at least one of GaN, InGaN, InN, AllnN, AlGaN, AllnGaN, AlN, GaAs, GaP, InP, AlGaAs, AllnGaAs, AlGalnP, InGaAs, InGaAsN, AllnAs, AllnP, AlGaP, InGaP, GaSb, InSb, InAs, InAsSb, AlGaSb, AISb, InGaSb, AlGaAsSb, InGaAsSb, SiC, Ga₂O₃, BN, and diamond.

In some embodiments, a thickness of each of the well layers may be within a range of 10 angstroms to 120 angstroms. A thickness of each of the barrier layers may be within a range of 10 angstroms to 200 angstroms.

In some embodiments, a refractive index coefficient of each of the well layers may be greater than or equal to a refractive index coefficient of each of the barrier layers.

The refractive index coefficient refers to a ratio of a speed of light propagation in vacuum to a speed of light propagation in a medium (e.g., the well layers or the barrier layers).

In some embodiments, a dielectric constant of each of the well layers may be greater than or equal to a dielectric constant of each of the barrier layers.

The dielectric constant refers to a ratio of an electric field strength inside the medium (e.g., the well layers and the barrier layers) to an electric field strength outside the medium.

In some embodiments, a piezoelectric polarization coefficient of each of the well layers may be greater than or equal to a piezoelectric polarization coefficient of each of the barrier layers.

The piezoelectric polarization coefficient may be used to characterize a degree of polarization generated in the well layers or the barrier layers under the effect of an external electric field.

In some embodiments of the present disclosure, the active layer may be the periodic structure composed of the well layers and the barrier layers. The refractive index coefficient of each of the well layers of the active layer may be greater than or equal to the refractive index coefficient of each of the barrier layers of the active layer. The dielectric constant of each of the well layers of the active layer may be greater than or equal to the dielectric constant of each of the barrier layers of the active layer. The piezoelectric polarization coefficient of each of the well layers of the active layer may be greater than or equal to the piezoelectric polarization coefficient of each of the barrier layers of the active layer, so that the photon degeneracy may be enhanced and the symmetry between the conduction band and the heavy-hole band may be improved. Under a same injection current, quasi-Fermi levels in the conduction band and the heavy-hole band may equally enter respective energy bands, reducing a threshold current density required for achieving population inversion. As a result, the excited radiation of the semiconductor laser may exceed the spontaneous radiation, enhancing the coherence of the transverse modes, the confinement factor, and the slope efficiency. In addition, the count of the longitudinal modes and the intermodal variations may be reduced, thereby improving the temporal coherence of the longitudinal modes, the FFP quality of the far-field image, the beam quality factor, and the focusing spot resolution.

In some embodiments, the active layer 103 may include a first active layer and a second active layer.

The first active layer refers to a thin layer that is partially split off from the active layer. The first active layer may include well layers and barrier layers of the first active layer.

The second active layer refers to a thin layer that is split off from the active layer and is different from the first active layer. The second active layer may include well layers and barrier layers of the second active layer.

In some embodiments, the refractive index coefficients of the well layers and the barrier layers of the first active layer may be denoted as A and B, respectively, the refractive index coefficients of the well layers and the barrier layers of the second active layer may be denoted as C and D, respectively, and 2.0≤B≤D≤A≤C≤3.0. For example, the refractive index coefficients of the well layers and the barrier layers of the first active layer may be denoted as A=2.8 and B=2.0, respectively, and the refractive index coefficients of the well layers and the barrier layers of the second active layer may be denoted as C=3.0 and D=2.5, respectively.

In some embodiments, the dielectric constants of the well layers and the barrier layers of the first active layer may be denoted as E and F, respectively, the dielectric constants of the well layers and the barrier layers of the second active layer may be denoted as G and H, respectively, and 8 $ G $ E $ H≤F≤12. For example, the dielectric constants of the well layers and the barrier layers of the first active layer may be denoted as E=9 and F=12, respectively, and the dielectric constants of the well layers and the barrier layers of the second active layer may be denoted as G=8 and H=10, respectively.

In some embodiments, the piezoelectric polarization coefficients of the well layers and the barrier layers of the first active layer may be denoted as I and J, respectively, the piezoelectric polarization coefficients of the well layers and the barrier layers of the second active layer may be denoted as K and L, respectively, and 0.7≤J≤L≤I≤K≤1.0. For example, the piezoelectric polarization coefficients of the well layers and the barrier layers of the first active layer may be denoted as I=0.85 and J=0.7, respectively, and the piezoelectric polarization coefficients of the well layers and the barrier layers of the second active layer may be denoted as K=1.0 and L=0.80, respectively.

In some embodiments of the present disclosure, by setting the dielectric constants of the well layers and the barrier layers of the first active layer as E and F, respectively, and the dielectric constants of the well layers and the barrier layers of the second active layer as G and H, respectively, wherein 8 $ G $ E≤H≤F≤12; and setting the piezoelectric polarization coefficients of the well layers and the barrier layers of the first active layer as I and J, respectively, and the piezoelectric polarization coefficients of the well layers and the barrier layers of the second active layer as K and L, respectively, wherein 0.7≤J≤L≤I≤K≤1.0, the photon degeneracy of the active layer and the symmetry between the conduction band and the heavy-hole band of the semiconductor laser may be further enhanced. Under the same injection current, the quasi-Fermi levels in the conduction band and the heavy-hole band may equally enter respective energy bands, reducing the threshold current density required for achieving population inversion. As a result, the excited radiation of the semiconductor laser may exceed the spontaneous radiation, enhancing the coherence of the transverse modes, the confinement factor, and the slope efficiency. In addition, the count of the longitudinal modes and the intermodal variations may be reduced, thereby improving the temporal coherence of the longitudinal modes, the FFP quality of the far-field image, the beam quality factor, and the focusing spot resolution.

In some embodiments, the refractive index coefficient, the dielectric constant, and the piezoelectric polarization coefficient of the first active layer may have a W-shaped distribution.

The refractive index coefficient having the W-shaped distribution refers to that a calculated refractive index coefficient in each of a plurality of regions defined in the first active layer has the W-shaped distribution. The first active layer may be divided into the plurality of regions in various ways, such as equally dividing the first active layer into m1 regions, wherein m1≥2 and m1 may be a positive integer.

The dielectric constant having the W-shaped distribution and the piezoelectric polarization coefficient having the W-shaped distribution may have a similar meaning as the refractive index coefficient having the W-shaped distribution of as described above.

In some embodiments, the refractive index coefficient, the dielectric constant, and the piezoelectric polarization coefficient of the second active layer may have an M-shaped distribution.

The refractive index coefficient having the M-shaped distribution refers to that a calculated refractive index coefficient in each of a plurality of regions defined in the second active layer has the M-shaped distribution. The second active layer may be divided into the plurality of regions in various ways, such as equally dividing the second active layer into m1 regions, wherein m1≥2 and m1 may be a positive integer.

The dielectric constant having the M-shaped distribution and the piezoelectric polarization coefficient having the M-shaped distribution may have a similar meaning to the refractive index coefficient having the M-shaped distribution as described above.

In some embodiments of the present specification, the refractive index coefficient, the dielectric constant, and the piezoelectric polarization coefficient of the first active layer may have the W-shaped distribution, and the refractive index coefficient, the dielectric constant, and the piezoelectric polarization coefficient of the second active layer may have the M-shaped distribution, so that the photon degeneracy of the active layer and the symmetry between the conduction band and the heavy-hole band of the semiconductor laser may be further enhanced. Under the same injection current, the quasi-Fermi levels in the conduction band and the heavy-hole band may equally enter respective energy bands, reducing the threshold current density required for achieving population inversion. As a result, the excited radiation of the semiconductor laser may exceed the spontaneous radiation, enhancing the coherence of the transverse modes, the confinement factor, and the slope efficiency. In addition, the count of the longitudinal modes and the intermodal variations may be reduced, thereby improving the temporal coherence of the longitudinal modes, the FFP quality of the far-field image, the beam quality factor, and the focusing spot resolution.

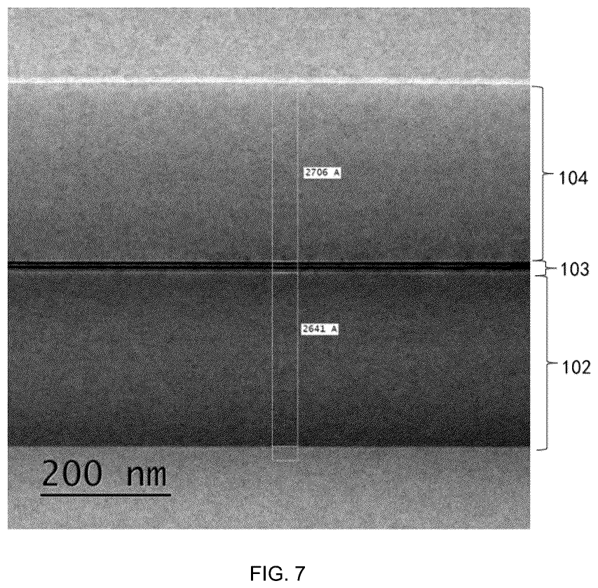

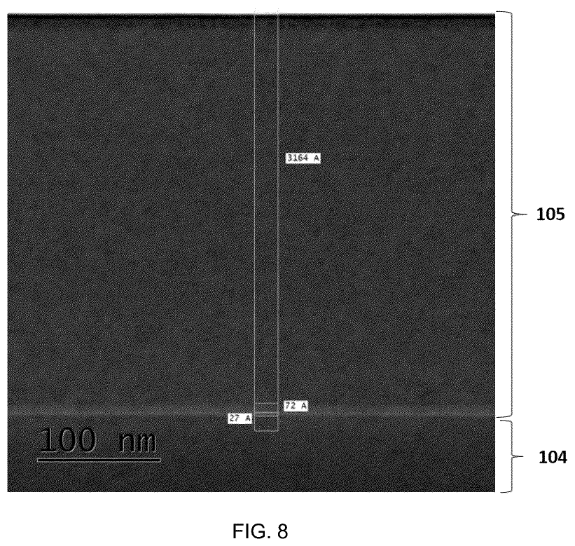

FIG. 7 is a transmission electron microscope (TEM) image of an upper waveguide layer and a lower waveguide layer of a semiconductor laser obtained by a TEM with a size of 200 nm according to some embodiments of the present disclosure. FIG. 8 is a transmission electron microscope (TEM) image of an upper limiting layer of a semiconductor laser obtained by a TEM with a size of 100 nm according to some embodiments of the present disclosure.

As illustrated in FIGS. 7-8, in some embodiments, the upper waveguide layer 104 may be a waveguide layer for suppressing optical absorption loss.

In some embodiments, the upper waveguide layer 104 may be composed of at least one of GaN, InGaN, InN, AllnN, AllnGaN, AlN, GaAs, GaP, InP, AlGaAs, AllnGaAs, AlGalnP, InGaAs, AllnAs, AllnP, AlGaP, InGaP, GaSb, InSb, InAs, AlGaSb, AISb, InGaSb, AlGaAsSb, InGaAsSb, SiC, Ga₂O₃, BN, and diamond.

In some embodiments, a thickness of the upper waveguide layer 104 may be within a range of 200 angstroms to 8000 angstroms.

In some embodiments, a conduction band effective density distribution, an electron affinity energy distribution, and a breakdown field strength distribution of the upper waveguide layer 104 may present an arc-shaped distribution.

A conduction band effective density refers to a distribution density of crystal electrons in a unit wave vector space of a conduction band.

The conduction band effective density distribution refers to a distribution of conduction band effective densities in each of a plurality of regions defined in the upper waveguide layer. The upper waveguide layer may be divided into the plurality of regions in various ways. For example, the upper waveguide layer may be equally divided into m2 regions, wherein m2≥2 and m2 may be a positive integer.

A breakdown field strength refers to a maximum electric field strength that a region of the upper waveguide layer can withstand to avoid breakdown under the action of an electric field.

The breakdown field strength distribution refers to a distribution of breakdown field strengths in each of the plurality of regions defined in the upper waveguide layer.

In some embodiments, the conduction band effective density distribution may correspond to a curvilinear distribution of a fifth function, the fifth function being denoted as y=logᵥ×(0<v<1).

In some embodiments, the electron affinity energy distribution may correspond to a curvilinear distribution of a sixth function, the sixth function being denoted as y=log_{w}X (w>1).

In some embodiments, the breakdown field strength distribution may correspond to a curvilinear distribution of a seventh function, the seventh function being denoted as y=log_{z}×(z>1); wherein 0<v<1<w<z<500.

In some embodiments of the present disclosure, the conduction band effective density distribution, the electron affinity energy distribution, and the breakdown field strength distribution of the upper waveguide layer may present the arc-shaped distribution, so that an optical field isolation and confinement region may be formed to prevent the optical field spreading to the upper limiting layer, thereby reducing the impurity light absorption loss and the defect light absorption loss in the upper limiting layer. Moreover, the refractive index dispersion may be regulated, reducing refractive index fluctuations of the semiconductor laser under a high carrier concentration, and reducing the carrier optical absorption loss and the sidewall scattering loss in waveguide structures, thereby reducing the optical absorption loss in the semiconductor laser, and improving the confinement factor and the optical power.

The lower waveguide layer 102 may serve as an optical transmission channel in the semiconductor laser.

The upper limiting layer 105 may be configured to limit the injection of electrons and holes in the semiconductor laser and the propagation of light

In some embodiments, the lower waveguide layer 102 and the upper limiting layer 105 may be respectively composed of at least one of GaN, InGaN, InN, AllnN, AllnGaN, AlN, GaAs, GaP, InP, AlGaAs, AllnGaAs, AlGalnP, InGaAs, AllnAs, AllnP, AlGaP, InGaP, respectively, GaSb, InSb, InAs, AlGaSb, AISb, InGaSb, AlGaAsSb, InGaAsSb, SiC, Ga₂O₃, BN, and diamond.

In some embodiments, a thickness of the lower waveguide layer 102 may be within a range of 10 angstroms to 50,000 angstroms.

In some embodiments, a thickness of the upper limiting layer 105 may be within a range of 10 angstroms to 80,000 angstroms.

The substrate 100 refers to a material base used for fabricating the semiconductor laser. For example, the substrate may be a wafer made of a semiconductor monocrystalline material.

In some embodiments, the substrate 100 may include any one of sapphire, Si, Ge, SiC, AlN, GaN, GaAs, Cu, W, Mo, TiW, GaSb, InSb, InP, a sapphire/SiO₂ composite substrate, a sapphire/AlN composite substrate, sapphire/SiNₓ, magnesium aluminum spinel MgAl₂O₄, MgO, ZnO, MgO, spinel, ZrB₂, diamond, LiAlO₂, and a LiGaO₂ composite substrate.

A comparison table showing a magnitude of change between individual blue laser-items of conventional lasers and the semiconductor laser described in the present disclosure is illustrated.

| | | Semiconductor | |
|---|---|---|---|
| | | laser of | Magnitude |
| | Conventional | the present | of |
| Blue laser-Item | lasers | disclosure | Change |
| Beam quality factor M² | 3.7 | 2.35 | 57% |
| Slope efficiency (W/A) | 0.8 | 1.76 | 120% |
| Threshold current density | 2.4 | 0.87 | −64% |
| (kA/cm²) | | | |
| Optical power (W) | 5.2 | 12.9 | 148% |
| 1000 H aging light decay | 22% | 4% | −84% |
| Confinement factor | 1.50% | 2.89% | 93% |
| Internal optical loss (cm⁻¹) | 17.2 | 11.6 | −33% |
| Focusing spot resolution (nm) | >200 | <40 | |

It can be seen from the table that compared with the conventional lasers, the semiconductor laser of the present disclosure has improved threshold current density from 2.4 (kA/cm²) to 0.87 (kA/cm²), 1000H aging optical decay from 22% to 4%, internal optical loss from 17.2 (cm⁻¹) to 11.6 (cm⁻¹), focusing spot resolution from over 200 nm to be less than 40 nm, slope efficiency from 0.8 (W/A) to 1.76 (W/A), beam quality factor from 3.7 M2 to 2.35 M², optical power from 5.2 W to 12.9 W, and confinement factor from 1.50% to 2.89%, thereby suppressing Auger non-radiative recombination efficiency, reducing the heat generated by the non-radiative recombination loss and the free carrier absorption loss, reducing the heat buildup in the active layer, improving the thermal conductivity and the heat dissipation, and improving the aging optical decay and the focusing spot resolution of the semiconductor laser.

The above shows and describes the basic principles, main features, and advantages of the present disclosure. Those skilled in the art should understand that the present disclosure is not limited by the above embodiments, and that the above embodiments and the description in the disclosure are only illustrative of the principles of the present disclosure, and that there may be various changes and improvements to the present disclosure without departing from the spirit and scope of the present disclosure, which fall within the scope of the present disclosure for which protection is claimed. The scope of protection claimed herein is defined by the appended claims and their equivalents.

The basic concept has been described above. Obviously, for those skilled in the art, the above detailed disclosure is only an example, and does not constitute a limitation to the present disclosure. Although not expressly stated here, those skilled in the art may make various modifications, improvements and corrections to the present disclosure. Such modifications, improvements and corrections are suggested in this disclosure, so such modifications, improvements and corrections still belong to the spirit and scope of the exemplary embodiments of the present disclosure.

Meanwhile, the present disclosure uses specific words to describe the embodiments of the present disclosure. For example, “one embodiment”, “an embodiment”, and/or “some embodiments” refer to a certain feature, structure or characteristic related to at least one embodiment of the present disclosure. Therefore, it should be emphasized and noted that references to “one embodiment” or “an embodiment” or “an alternative embodiment” two or more times in different places in the present disclosure do not necessarily refer to the same embodiment. In addition, certain features, structures or characteristics in one or more embodiments of the present disclosure may be properly combined.

In the same way, it should be noted that in order to simplify the expression disclosed in this disclosure and help the understanding of one or more embodiments of the invention, in the foregoing description of the embodiments of the present disclosure, sometimes multiple features are combined into one embodiment, drawings or descriptions thereof. This method of disclosure does not, however, imply that the subject matter of the disclosure requires more features than are recited in the claims. Rather, claimed subject matter may lie in less than all features of a single foregoing disclosed embodiment.

In some embodiments, counts describing the quantity of components and attributes are used. It should be understood that such counts used in the description of the embodiments use the modifiers “about”, “approximately” or “substantially” in some examples. Unless otherwise stated, “about”, “approximately” or “substantially” indicates that the stated figure allows for a variation of +20%. Accordingly, in some embodiments, the numerical parameters used in the disclosure and claims are approximations that can vary depending upon the desired characteristics of individual embodiments. In some embodiments, numerical parameters should consider the specified significant digits and adopt the general digit retention method. Although the numerical ranges and parameters used in some embodiments of the present disclosure to confirm the breadth of the range are approximations, in specific embodiments, such numerical values are set as precisely as practicable.

Each of the patents, patent applications, publications of patent applications, and other material, such as articles, books, specifications, publications, documents, things, and/or the like, referenced herein is hereby incorporated herein by this reference in its entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that may be employed may be within the scope of the application. Thus, by way of example, but not of limitation, alternative configurations of the embodiments of the application may be utilized in accordance with the teachings herein. Accordingly, embodiments of the present application are not limited to that precisely as shown and described.

1. A semiconductor laser, from bottom to top, comprising: a substrate, a lower limiting layer, a lower waveguide layer, an active layer, an upper waveguide layer, and an upper limiting layer; wherein the lower limiting layer is composed of at least one of AllnGaN, AllnN, AlGaN, InN, AlN, InGaN, and GaN, and a thickness of the lower limiting layer is denoted as x, wherein 10 angstroms≤x≤90,000 angstroms; and the lower limiting layer includes a first lower limiting layer, a second lower limiting layer, and a third lower limiting layer; wherein
a thermal conductivity distribution and an electron effective mass distribution of the second lower limiting layer have an “U”-shaped distribution, and a Phillips ionicity distribution and an electron affinity energy distribution of the second lower limiting layer have an inverted “U”-shaped distribution;
a ratio of a content of an element In to a content of an element Mg of the second lower limiting layer and a ratio of a content of an element Si to the content of the element Mg of the second lower limiting layer have an inverted “U”-shaped distribution, and a ratio of a content of an element Al to the content of the element Mg of the second lower limiting layer has a “U”-shaped distribution; and
the upper limiting layer is composed of at least one of GaN, InGaN, InN, AllnN, AllnGaN, AlN, GaAs, GaP, InP, AlGaAs, AllnGaAs, AlGalnP, InGaAs, AllnAs, AllnP, AIGaP, InGaP, GaSb, InSb, InAs, AlGaSb, AISb, InGaSb, AlGaAsSb, InGaAsSb, SiC, Ga2O3, BN, and diamond.

2-4. (canceled)

5. The semiconductor laser of claim 1, wherein the thermal conductivity distribution of the second lower limiting layer corresponds to a curvilinear distribution of a first function, the first function being denoted as y=ix²+jx+k (i>0), the electron effective mass distribution of the second lower limiting layer corresponds to a curvilinear distribution of a second function, the second function being denoted as y=mx²+nx+o (m>0), the Phillips ionicity distribution of the second lower limiting layer corresponds to a curvilinear distribution of a third function, the third function being denoted as y=px²+qx+r (p<0), and the electron affinity energy distribution of the second lower limiting layer corresponds to a curvilinear distribution of a fourth function, the fourth function being denoted as y=sx²+tx+u (s<0), wherein s<p<0<i≤m, and j, k, n, o, q, r, t, and u are any preset values.

6-10. (canceled)

11. The semiconductor laser of claim 1, wherein thermal conductivities of the first lower limiting layer, the second lower limiting layer, and the third lower limiting layer are denoted as a, b, and c, respectively, wherein 2.5 (10⁻⁶/K)≤b≤a≤c≤5.5 (10⁻⁶/K); electron effective masses of the first lower limiting layer, the second lower limiting layer, and the third lower limiting layer are denoted as d, e, and f, respectively, wherein 200 GPa≤e≤f≤d≤400 GPa; and Phillips ionicities of the first lower limiting layer, the second lower limiting layer, and the third lower limiting layer are denoted as g, h, and I, respectively, wherein 3≤i≤g≤h≤4.

12. The semiconductor laser of claim 1, wherein the active layer is a periodic structure composed of well layers and barrier layers, and the periodic structure includes 1-3 sets of well layers and barrier layers; each of the well layers and each of the barrier layers are composed of at least one of GaN, InGaN, InN, AllnN, AlGaN, AllnGaN, AlN, GaAs, GaP, InP, AlGaAs, AllnGaAs, AlGalnP, InGaAs, InGaAsN, AllnAs, AllnP, AIGaP, InGaP, GaSb, InSb, InAs, InAsSb, AlGaSb, AISb, InGaSb, AlGaAsSb, InGaAsSb, SiC, Ga2O3, BN, and diamond, and a thickness of the each of the well layers is within a range of 10 angstroms to 120 angstroms; a thickness of the each of the barrier layers is within a range of 10 angstroms to 200 angstroms; a refractive index coefficient of the each of the well layers is greater than or equal to a refractive index coefficient of the each of the barrier layers; a dielectric constant of the each of the well layers is greater than or equal to a dielectric constant of the each of the barrier layers; and a piezoelectric polarization coefficient of the each of the well layers is greater than or equal to a piezoelectric polarization coefficient of the each of the barrier layers.

13. The semiconductor laser of claim 12, wherein the active layer includes a first active layer and a second active layer; the refractive index coefficients of the well layers and the barrier layers of the first active layer are denoted as A and B, respectively, and the refractive index coefficients of the well layers and the barrier layers of the second active layer are denoted as C and D, respectively, wherein 2.0≤B≤D≤A≤C≤3.0; the dielectric constants of the well layers and the barrier layers of the first active layer are denoted as E and F, respectively, and the dielectric constants of the well layers and the barrier layers of the second active layer are denoted as G and H, respectively, wherein 8≤G≤E≤H≤F≤12; and the piezoelectric polarization coefficients of the well layers and the barrier layers of the first active layer are denoted as I and J, respectively, and the piezoelectric polarization coefficients of the well layers and the barrier layers of the second active layer are denoted as K and L, respectively, wherein 0.7≤J≤L≤I≤K≤1.0.

14. The semiconductor laser of claim 13, wherein the refractive index coefficient, the dielectric constant, and the piezoelectric polarization coefficient of the first active layer have a W-shaped distribution, and the refractive index coefficient, the dielectric constant, and the piezoelectric polarization coefficient of the second active layer have an M-shaped distribution.

15. The semiconductor laser of claim 1, wherein the upper waveguide layer is a waveguide layer for suppressing optical absorption loss; the upper waveguide layer is composed of at least one of GaN, InGaN, InN, AllnN, AllnGaN, AlN, GaAs, GaP, InP, AlGaAs, AllnGaAs, AlGalnP, InGaAs, AllnAs, AllnP, AIGaP, InGaP, GaSb, InSb, InAs, AlGaSb, AlSb, InGaSb, AlGaAsSb, InGaAsSb, SiC, Ga2O3, BN, and diamond, a thickness of the upper waveguide layer is within a range of 200 angstroms to 8000 angstroms; a conduction band effective density distribution, an electron affinity energy distribution, and a breakdown field strength distribution of the upper waveguide layer present an arc-shaped distribution; the conduction band effective density distribution corresponds to a curvilinear distribution of a fifth function, the fifth function being denoted as y=logᵥ×(0<v<1); the electron affinity distribution corresponds to a curvilinear distribution of a sixth function, the sixth function being denoted as y=log_{w}×(w>1); and the breakdown field strength distribution corresponds to a curvilinear distribution of a seventh function, the seventh function being denoted as y=log_{z}×(z>1); wherein 0<v<1<w<<<500.

16. The semiconductor laser of claim 1, wherein the lower waveguide layer is composed of at least one of GaN, InGaN, InN, AllnN, AllnGaN, AlN, GaAs, GaP, InP, AlGaAs, AllnGaAs, AlGalnP, InGaAs, AllnAs, AllnP, AIGaP, InGaP, GaSb, InSb, InAs, AlGaSb, AlSb, InGaSb, AlGaAsSb, InGaAsSb, SiC, Ga2O3, BN, and diamond; a thickness of the lower waveguide layer is within a range of 10 angstroms to 50,000 angstroms; a thickness of the upper limiting layer is within a range of 10 angstroms to 80,000 angstroms; and the substrate includes any one of sapphire, Si, Ge, SiC, AlN, GaN, GaAs, Cu, W, Mo, TiW, GaSb, InSb, InP, a sapphire/SiO2 composite substrate, a sapphire/AlN composite substrate, sapphire/SiNx, magnesium aluminum spinel MgAl2O4, MgO, ZnO, MgO, spinel, ZrB2, diamond, LiAlO2, and a LiGaO2 composite substrate.
